(19) United States
(12) Patent Application Publication
(10) Pub. No.: US 2025/0379061 A1
(43) Pub. Date: Dec. 11, 2025

(54) METHOD FOR PRODUCING A THROUGH-OPENING IN A GERMANIUM SEMICONDUCTOR WAFER HAVING OVERLYING III-V SEMICONDUCTOR LAYERS

(71) Applicant: AZUR SPACE Solar Power GmbH, Heilbronn (DE)

(72) Inventors: Wolfgang KOESTLER, Heilbronn (DE); Benjamin HAGEDORN, Ilsfeld (DE)

(73) Assignee: AZUR SPACE Solar Power GmbH, Heilbronn (DE)

(21) Appl. No.: 19/231,870

(22) Filed: Jun. 9, 2025

(30) Foreign Application Priority Data
Jun. 7, 2024 (DE) 10 2024 001 861.1

(51) Int. Cl. H01L 21/308; H01L 21/306

(52) U.S. Cl. CPC H01L 21/3083; H01L 21/30604

(57) ABSTRACT

A method for producing a through-opening in a germanium semiconductor wafer having overlying III-V layers and a front side with multiple III-V layers. First resist-free regions are formed in a first photolithography process for forming the through-opening, or the first resist is applied in a patterned manner by a first printing process. A recess having circumferential side surfaces and a base region is subsequently formed from the front side of the germanium layer. A second resist is applied by a second photolithography process, and second resist-free regions are formed in the base region, or the second resist is applied in a patterned manner by a second printing process to form the second resist-free regions. A through-hole extending from the base region of the recess to the back side of the wafer is produced in the germanium layer in the second resist-free regions of the base region.

This nonprovisional application claims priority under 35 U.S.C. § 119 (a) to German Patent Application No. 10 2024 001 861.1, which was filed in Germany on Jun. 7, 2024, and which is herein incorporated by reference.

### BACKGROUND OF THE INVENTION

### Field of Invention

The present invention relates to a through-opening that forms an electrical connection from a top surface of the semiconductor wafer having overlying III-V semiconductor layers to a back side of the semiconductor wafer. The top surface may be electrically contacted hereby from the back side. In other word, a back-side top surface connection is formed.

### Description of the Background Art

A method is known from DE 10 2019 006 094 A1, which corresponds to US 2021/0066534, which is incorporated herein by reference, for producing a through-opening in a germanium semiconductor wafer having overlying III-V layers, different process steps being carried out to produce the through-opening. Among other things, a second opening is produced in a second resist layer on an upper side of the semiconductor wafer in a second resist process, the second opening being larger than the opening already present on the upper side, and the second opening enclosing the existing opening.

### SUMMARY OF THE INVENTION

It is therefore an object of the invention to provide a method and a device which refines the prior art.

In an example, the object is achieved by a method for producing a through-opening in a germanium III-V semiconductor wafer having overlying III-V layers.

With the aid of the method, a through-opening is produced in a germanium semiconductor wafer having overlying III-V layers.

The germanium semiconductor wafer can have a diameter of at least 100 mm and a thickness of more than 80 μm.

The germanium semiconductor wafer also can have a back side and a front side and is designed as a substrate.

Multiple III-V layers can be formed on the front side of the germanium wafer, a portion of the III-V layers forming a top surface of the semiconductor wafer.

A first resist can be patterned on the top surface in a first photolithography process, first resist-free regions being formed during the patterning for forming the through-opening.

Also, the first resist can be applied in a patterned manner by means of a first printing process to form the first resist-free regions.

An advantage of the first printing process, compared to the first photolithography process, is that, among other things, a complex exposure and development of the first resist is omitted. In other words, the first resist is applied during the first printing process only in the regions to be coated with resist, i.e., the first resist is not applied in the regions for forming the through-opening.

In a subsequent step, the III-V layers situated on the front side of the germanium semiconductor wafer are wet-chemically removed in the first resist-free regions to form an oval hole-like recess having surrounding side surfaces and a base region from the front side of the germanium semiconductor wafer.

The term “oval” may be understood to be round, in particular circular, shapes as special cases, as well as elongated, elliptical patterns.

The first resist can be completely removed after the etching. The removal of the resist can be carried out with the aid of a plasma ashing step and a subsequent cleaning step.

In a further method step, after the removal of the first resist, a second resist can be applied by means of a second photolithography process and patterned in the base region of the recess to form second resist-free regions in the base region. It can be understood that, after a resist-coating process, as part of the second photolithography process, the second resist also can completely cover the side surfaces and the base region of the opening on the upper side of the III-V layers in the region of the opening beyond the boundary of the opening, and the resist-free regions in the base region form only after the patterning within the photolithography process.

Also, to the second photolithography process, the second resist can already be applied in a patterned manner by means of a second printing process to form the second resist-free regions in the base region.

An advantage of the second printing process, corresponding to the advantages of the first printing process, is that a complex exposure and development of the second resist is omitted. In other words, the second resist is applied only in the regions to be coated with resist in the second printing process.

The second resist can also be applied to the side surfaces, i.e., the surrounding side surfaces of the recess are completely covered by the second resist to protect the side surfaces against an etching attack. In other words, in addition to the circumferential boundary region on the top surface of the III-V layers as well as the side surfaces, a circumferential boundary region on the base is also covered by the resist during the printing process, so that a second resist-free region is formed in the base region.

The second resist-free regions can be formed in a central region of the base of the recess. In other words, a completely circumferential boundary region in connection with the side surfaces is covered by the second resist in the base region.

In the second resist-free regions of the base region, a through-hole extending from the base region of the recess to the back side of the semiconductor wafer can be produced in the germanium layer by means of a laser process. The laser should be applied only in the second resist-free regions, and a circumferential, step-shaped shoulder connected to the side surfaces or a first step is formed in the base region.

The first step in the base region of the recess may run along the particular side surfaces, and the step surface of the first step can be made up of germanium.

The term “maximum width” should refer to the diameter of the shape in the recess as well as in the through-hole in the case of a round design. In the case of other examples, i.e., which are not round, the term “maximum width” can refer in each case to the maximum distance from two side surface sections situated opposite each other along a straight line running in parallel to the top surface.

Correspondingly, the term “minimum width” may refer to the shortest distance, always the diameter of the shape in the case of a round design, while in the other non-round designs, the term refers in each case to the minimum distance from two side surface sections situated opposite each other along a straight line running in parallel to the top surface.

In the case of a round design, the maximum width and the minimum width should be exactly the same size and each refer specifically to the diameter.

The term “the extension of the recess” or “the extension of the through-hole” should refer to the size of the opening resulting in each case from the minimum width and the maximum width.

The through-opening can be made up of the recess having the first width and the first circumferential step in the base region of the recess and the through-hole having a second circumferential step, formed exclusively in the germanium, on the upper boundary of the hole, the second width of the through hole being smaller than the first width. It is understood that the second width is smaller than the first width at least by the depth of the step surface.

The recess can begin at the top surface and has an upper edge to the second step at the top surface. The recess has a lower edge at the end of the recess, i.e. at a transition of the side surface to the base surface. The first width refers to the size of the opening at the upper edge of the recess, while the size of the recess has a third width at the lower edge.

If the side surfaces of the recess are perpendicular or perpendicular in a first approximation, the third width is the same size as the first width or slightly smaller.

The third width can be smaller by at least 0.1 μm and no more than 2 μm.

It should also be noted that the through-hole begins in the base region, i.e., on the front side of the germanium layer, and can have a first edge on the front side.

The through-hole can have a second edge at the end of the through-hole, i.e., at a transition of the side surface of the through-hole to the back side of the germanium layer. The second width refers to the size of the opening at the upper edge of the through-hole, while the size of the through-hole has a fourth width at the lower edge.

If the side surfaces of the through-hole are designed to be perpendicular, the fourth width is the same size as the second width.

The through-hole can be designed to be conical along the depth extension, i.e., the fourth width is smaller than the second width.

The fourth width can be smaller by at least 0.5 μm and no more than 10 μm.

The particular width may refer in each case to the diameter of the circle in the case of a circular design as a special case of the general oval example.

It should furthermore be noted that, in the present case, the terms “germanium semiconductor wafer” and “semiconductor wafer” can be used synonymously.

Oval through-holes can be generated with the aid of the laser.

The through-holes can be designed to be circular.

The second resist-free regions can be formed in a central region of the base, and a circumferential step edge of the first step is formed after the formation of the through-hole.

In a subsequent second wet-etching step, the through-hole can be overetched and a portion of the germanium layer is removed. The second step can be formed with a second step edge.

In a further step, the second resist can be completely removed to form the through-opening, the width of the recess in the through-opening being larger than the width of the through-hole.

It should be noted that different etching solutions or different acids can be used in the first wet etching step and in the second wet etching step. The two terms “etching solution” and “acid” can be used synonymously below.

In particular, the acid used in the first wet etching step can have a different composition than the etching solution used in the second wet etching step.

The acid used in carrying out the first wet etching step can have a reduced etching rate against germanium than against the III-V layers.

An advantage is that the time period for the wet etching is not sensitive with respect to an etching of the germanium layer, and the III-V layers may be reliably and, in particular, completely removed hereby in the base region of the recess.

The acid in the first wet etching step can have no or only a very limited etching rate against germanium. This allows the front side of the germanium semiconductor wafer to be particularly easily and reliably exposed in the base region of the recess.

The term “III-V layers” can refer to a sequence of layers, each made up of a III-V compound, at least two directly consecutive layers having a different stoichiometry and/or a different material composition.

The III-V layers can comprise one or multiple solar cells. In the case of multiple solar cells, between two and seven or between three and five solar subcells are stacked one on top of the other and connected in series with the aid of tunnel diodes situated therebetween.

A n/p junction, i.e., a solar cell, is formed on the front side or in the front side of the germanium layer.

A plurality of through-openings may also be produced on the top surface with the aid of the present method.

When using the method, in particular, for a multijunction solar cell, a low-resistance electrical contact of the top surface may form in the direction of the back side in the case of a multiplicity of through-openings, in that the electrical contacts may be arranged not only on the boundary but also in the middle of the solar cell or at arbitrary points on the top surface. In the case of large solar cell surfaces, in particular, the ohmic losses on the top surface at high currents may be reduced hereby.

A further advantage of the method is that one or multiple through-openings may be reliably and cost-effectively produced in an easy and particularly economical manner on the top surface of the semiconductor wafer, in particular for a formation of electrical through-contactings.

Another advantage is that the size of metal surfaces on the front side may be reduced by means of the back-side contacting. The size of the receiving surface may be increased hereby when forming one or multiple solar cells on the front side.

In particular, the use of wet etching processes makes expensive and complex dry etching processes unnecessary.

Another advantage is that, by carrying out the second wet etching step after the formation of the through-hole by means of a laser process step, any deposits that may be present may be easily and quickly removed by the evaporation of germanium in the regions having the second resist.

The through-hole can be overetched by the second wet etching step and cleaned of remnants of the laser process. In other words, the second wet etching process reliably, quickly and cost-effectively removes the impurities caused by the laser process on both the top surface and the underside as well as in the through-hole.

It has surprisingly been shown that steep side surfaces may be formed without an overetching in the III-V layers by means of the first wet etching step in forming the oval recess. In other words, the width on the top surface of the recess is only slightly larger or not larger than the width on the underside of the recess, i.e., in the base region.

The extension of the opening of the recess at the top surface can be in a range between 0.0 μm and 50 μm or in a range between 0.5 μm and 30 μm or in a range between 1.0 μm and 15 μm larger than the extension of the opening of the recess in the base region.

The extension of the opening of the recess can be a width in a range between 40 μm and 500 μm at the top surface, i.e., at the upper edge.

The top surface having the first resist can be protected against an etching attack outside the recesses to be produced when carrying out the first wet etching step.

The first resist of the first photolithography process can have the same chemical composition or a different chemical composition than the second resist of the second photolithography process.

The same resists or different resists can be used in the printing process than in the photolithography processes.

In that the side surfaces of the recess do not have an angle of slope greater than 90° or no undercutting, the side surfaces may be reliably covered with the resist in the second photolithography process for the purpose of protecting the III-V layers on the side surfaces against an etching attack when carrying out the second wet etching step.

The term “steep side surfaces” in the recess may be understood to be an angle of slope greater than 45° or an angle of slope in a range between 90° and 45°, starting from the base surface. In other words, the side surfaces of the recess do not have an angle greater than 90°.

In a first approximation or side surfaces having an angle of slope between 90° and 80° or having an angle of slope between 90° and 85° or exactly perpendicular, i.e., having an angle of slope of 90°, can be produced when carrying out the first wet etching process.

The side surfaces can comprise III-V layers or are made up predominantly of III-V layers, i.e., more than 50% of the surface area to more than 90% of the surface area or the side surfaces, are made up thereof.

The topography resulting in the side surfaces by the first etching process may remain unchanged until the second resist is applied during the second photolithography process.

The topography of the side surfaces can be unchanged even after the resist is removed in the second photolithography process, and the top surface has the same topography after the first etching process.

It should also be noted that, during the first photolithography process or during the printing process, only the regions for forming the through-opening may be free of resist on the top surface.

The III-V layers formed on the front side of the germanium semiconductor wafer can comprise at least one solar cell having an n/p junction.

The III-V layers can comprise binary and/or ternary and/or quaternary compounds, or the III-V layers are made up of binary and/or ternary and/or quaternary compounds. In particular, the III-V layers comprise or are made up of GaAs, InGaAs, (Al) InGaP, AlAs, InP and comprise dopants such as carbon and/or silicon.

The thickness of the individual III-V layer can be in a range between 0.01 μm and 30 μm.

The number of III-V layers arranged one on top of the other can be between 10 and 300 or between 20 and 150 or between 30 and 75.

A total thickness of the III-V layers can be in a range between 1 μm and 80 μm or in a range between 2 μm and 40 μm or in a range between 3 μm and 15 μm.

All or at least 90% of the III-V layers can be deposited over the entire surface. The III-V layers are preferably deposited by means of a vapor phase epitaxy method such as MOVPE.

The same number of p/n junctions can be formed on the entire top surface.

The III-V layers formed on the front side of the germanium semiconductor wafer can comprise at least one multijunction solar cell.

The multijunction solar cell can include exactly two or exactly three and no more than five solar subcells stacked one on top of the other, the solar subcells being electrically connected in series with the aid of tunnel diodes formed between the solar subcells.

A n layer can be formed on the front side of the germanium semiconductor wafer by means of inward diffusion of dopants. A Ge solar subcell may also be formed hereby in the germanium semiconductor wafer.

The solar cell stack can be the bottom solar subcell, the bottom solar subcell in the multijunction solar cell having the smallest band gap and absorbing in the red and infrared wavelength range.

The germanium semiconductor wafer or the Ge semiconductor substrate can be p-doped.

A n/p junction can be formed on the front side of the germanium layer, the n-doped germanium layer being completely removed by means of the second wet etching step, so that only the p-doped Ge semiconductor substrate is formed in the base region.

A metamorphic buffer can be formed between the bottom solar subcell and the directly following further solar subcell, the further solar subcell and the metamorphic buffer being made up or at least comprising III-V layers.

At least the side surfaces can be completely covered by the second resist when carrying out the second wet etching step and are completely protected hereby against an etching attack in the second wet etching step.

Not only the side surfaces of the recess, but also the top surface can be completely covered by the second resist during the second wet etching step and protected hereby against an etching attack.

In other words, with the exception of the resist-free surfaces in the base region, the top surface can be completely covered by the second resist during the second photolithography process.

The back side can be covered by a protective layer, preferably by a further resist, during the second photolithography process for the purpose of preventing an etching attack on the back side of the germanium semiconductor wafer.

The first photolithography process or the printing process can be applied only after the formation of a first metal contact system on the top surface and/or only after a formation of a second metal contact system on the back side.

The first metal contact system can be designed as a strip-shaped metallic printed conductor system on the top surface for the purpose of electrically contacting the solar cell during the formation of a single-junction or multijunction solar cell.

A metal layer can be formed on the back side, the metal layer not being formed in the region of the through-openings. The metal layer forms the second back-side metal contact system.

The first step can have a depth, i.e. a step surface, in a range between 0.05 μm and 20 μm or in a range between 0.2 μm and 10 μm or in a range between 0.5 μm and 5 μm or in a range between 0.2 μm and 195 μm or between 2 μm and 60 μm.

The second step can have a depth, i.e., a step surface, in a range between 0.02 μm and 10 μm or in a range between 0.1 μm and 5 μm or in a range between 0.5 μm and 4 μm or in a range between 0.2 μm and 20 μm.

The III-V layers in the resist-free regions can be completely removed when carrying out the first wet etching step, and the base region is preferably formed exclusively by the front side of the germanium semiconductor wafer.

The first resist can be formed over the entire top surface of the semiconductor wafer in a first process step during the first photolithography process, and the first resist is exposed and developed in a second process step for the purpose of establishing resist-free regions.

The acid in the first etching step can have a selectivity greater than 10:1 or greater than 30:1 or greater than 50:1, i.e., the III-V layers can be etched by the acid at least ten times or at least thirty times or at least fifty times faster than the germanium layer.

The acid can have exactly the same etching rate or a higher etching rate against germanium than against the III-V layers when carrying out the second wet etching step.

The through-opening can have a second step in addition to the first step.

The recess can have a maximum width at the top surface in a range between 40 μm and 500 μm or in a range between 2 μm and 100 μm or in a range between 4 μm and 40 μm.

The recess can have a minimum width at the top surface of more than 2 μm or more than 4 μm or more than 40 μm.

The through-hole produced with the aid of the laser can have a smaller maximum width and a smaller minimum width than the recess.

A circumferential step can be formed in the base region of the recess along the side surface when carrying out the laser process, the through-hole in the base surface having a maximum width in a range between at least 10 μm and no more than 400 μm or 20 μm to 200 μm, and a passage depth has a height corresponding to the thickness of the germanium layer.

The first photolithography process as well as the second photolithography process can each comprise, among other things, a coating step with the aid of a resist, a curing step, an exposure step with the aid of a mask, a development step including a removal of the resist in the exposed regions-if a positive resist is used.

If a printing process is carried out instead of the first photolithography process, it is sufficient if a curing step takes place after the patterned application of the first resist. An exposure step and a development step are omitted. It is understood that the application of the first resist when using the printing process can correspond to the application of a positive resist in the first photolithography process.

In a further method step, the particular wet etching or laser process and wet etching can each be subsequently carried out, and the resist can then be completely removed in the non-exposed regions with the aid of an ashing step and a cleaning step.

The extension of the recess can be determined in that the first resist is formed over the entire top surface of the semiconductor wafer in a first process step during the first photolithography process, and the first resist is exposed with a mask and developed in a second process step, or the first resist is alternatively formed in a patterned manner on the top surface of the semiconductor wafer by means of the first printing process.

The opening can be designed to be circular or as a circle in the recess and/or in the through-hole.

The III-V layers formed on the front side can have a total thickness between 1 μm and 80 μm or a total thickness between 2 μm and 40 μm or a total thickness between 3 μm and 15 μm.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIGS. 1a through 1i show a cross-sectional process sequence for producing a through-opening;

FIG. 2 shows a cross-sectional view of an example of the through-hole depicted in FIG. 1i;

FIG. 3a shows a top view of the top surface of the semiconductor wafer after the formation of the through-opening; and

FIG. 3b shows a top view of the back side of the semiconductor wafer after the formation of the through-opening.

### DETAILED DESCRIPTION

For reasons of clarity, the depicted patterns in the illustrated example have a circular design in a cross-section in parallel to a back side.

In an example, patterns may not have a circular design in a cross-section in parallel to a back side.

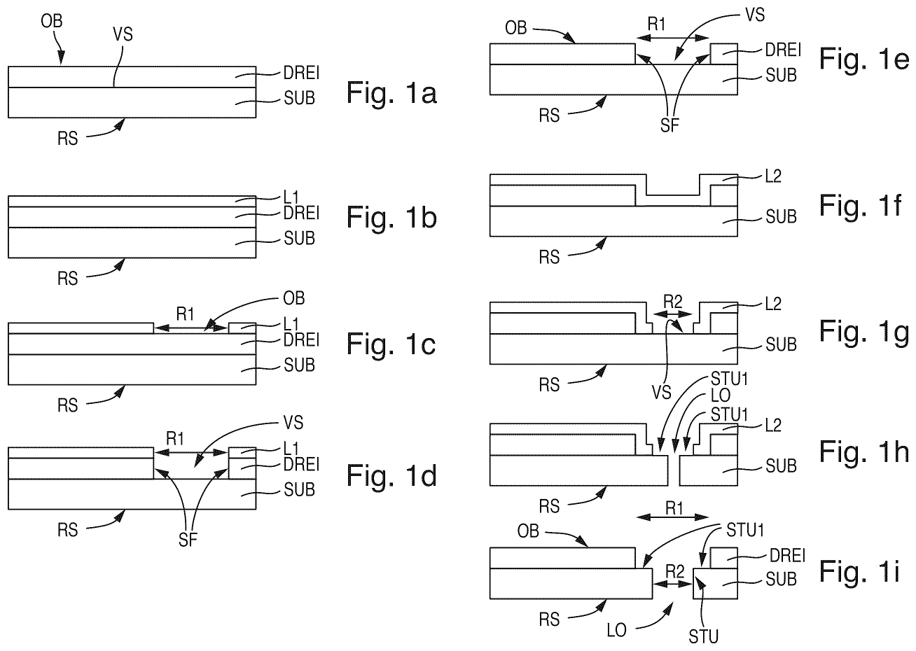

In FIGS. 1a through 1i, the individual steps for forming a through-opening are illustrated in a cross-sectional view. It is understood that all method steps are carried out on a semiconductor wafer WF and, for reasons of clarity, only the production of a single through-opening is shown in the cross-sectional illustrations.

It is furthermore possible to replace one photolithography process or both photolithography processes with a printing process in each case and to significantly reduce the number of process steps. The production of the through-opening with the use of the two photolithography processes is explained below.

The two resists L1 and L2 can each be applied by means of printing processes.

In a first step, illustrated in FIG. 1a, a germanium semiconductor wafer SUB is provided with a front side VS and a back side RS. An overlying layer sequence DREI of III-V layers is formed on front side VS.

Layer sequence DREI is grown by means of an epitaxy, preferably a MOVPE epitaxy method, and comprises a multiplicity of III-V layers made from different materials and dopings and has a top surface OB. For reasons of clarity, the individual III-V layers in overlying layer sequence DREI are not shown.

Top surface OB and back side RS are each provided with a planar design, with the exception of a scribe line, in particular, no metallization is depicted on either top surface OB or back side RS in the present cross-sectional illustrations.

It should be noted that the thickness of top surface OB encompassing the printed conductors is in a range of just a few μm. Apart from the thickness of the topography formed by the patterned metallization, top surface OB is designed to be planar. For reasons of clarity, the printed conductors at or on top surface OB are not illustrated.

In a second step, illustrated in FIG. 1b, top surface OB is coated all over with a first resist L1 by means of a first photolithography process. In the present case, a positive resist is used for this purpose.

In a third step, illustrated in FIG. 1c, first resist L1 is removed in a first region R1 on top surface OB after the first resist has been exposed and developed.

In a fourth step, illustrated in FIG. 1d, the III-V layers are etched away in first region R1 after a first wet etching step, so that the base of the oval pattern is formed from front side VS.

In a fifth step, illustrated in FIG. 1e, first resist L1 is removed completely, so that an oval pattern is formed in first region R1 on top surface OB. The oval pattern has almost perpendicular side surfaces SF. Side surfaces SF are made up of the III-V layers.

In a sixth step, illustrated in FIG. 1f, top surface OB and the oval pattern, including the base surface and side surfaces SF, are covered with a second resist L2 in a second photolithography process.

In a seventh step, illustrated in FIG. 1g, second resist R2 is removed in a second region R2 in the base region of the oval pattern, second resist L2 covering the top surface and side surfaces SF and a boundary of the base region. The width of second region R2 is smaller than the width of first region R1.

In an eighth step, illustrated in FIG. 1h, a through-hole LO is produced within second region R2 by means of a laser process. The width of the through-hole is smaller than the width of second region R2, and a first step STU1 is formed.

Second region R2 and through-hole LO are each designed to be circular. The width of second region R2 and the width of through-hole LO each correspond to the particular diameter. First step STU1 is provided with a circumferential design.

After through-hole LO is produced, the through-hole and the exposed regions are overetched in second region R2 with the aid of a second wet etching step.

Through-hole LO is expanded to size R2. Moreover, any Ge remnants or Ge particles or Ge deposits may be removed from the application of the laser process by means of the second etching process.

In that second region R2 is smaller than first region R1, a second circumferential step STU2 is formed in the region of the base.

In a ninth step, illustrated in FIG. 1i, second resist L2 is removed completely, and the through-opening, including second step STU2, is completely formed in the base region. It is understood that second step STU2 is formed exclusively in the Ge.

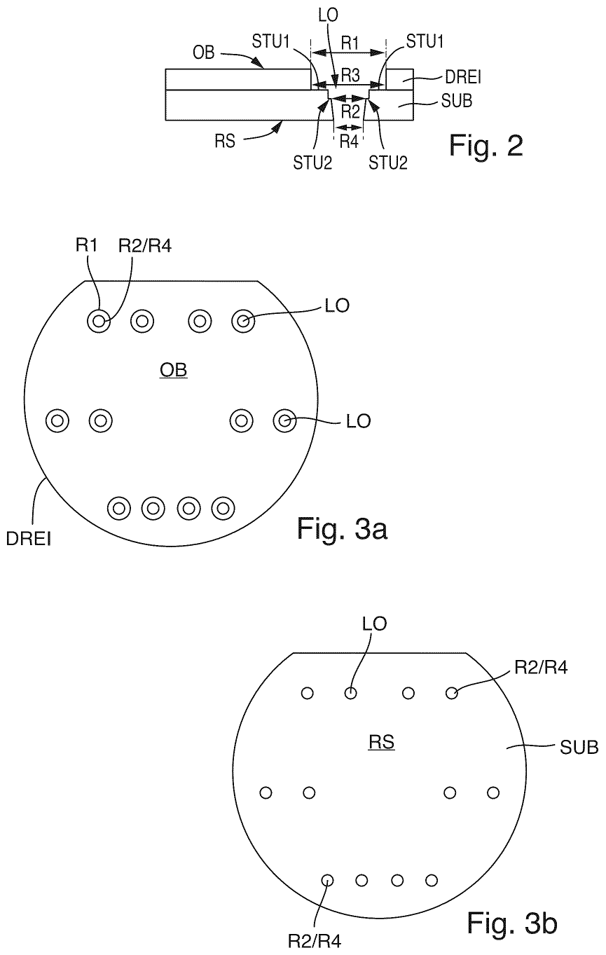

A cross-sectional view of an example of through-hole LO depicted in FIG. 1i is shown in the illustration in FIG. 2.

A difference from the example in FIG. 1i is that through-hole LO has a conical design, a lower edge having a fourth diameter R4, and fourth diameter R4 being smaller than second diameter R2. The lower edge is formed from planar back side RS and the end of the through-hole.

The illustration in FIG. 3a shows a top view of the top surface of the semiconductor wafer after the formation of multiple through-openings. Top surface OB is formed by one of III-V layers DREI. It is apparent that the through-openings may be formed in the boundary region as well as in a central region of the germanium wafer.

A strip-shaped metallic printed conductor system can be formed on top surface OB.

The illustration in FIG. 3b shows a top view of back side RS of semiconductor wafer SUB after the formation of the through-openings, as described in the example in connection with the illustration in FIG. 3a. The germanium layer is formed over the entire surface on back side RS.

A metal layer can be formed on the back side, the metal layer not being formed in the region of the through-openings.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for producing a through-opening in a germanium semiconductor wafer comprising overlying III-V semiconductor layers, the germanium semiconductor wafer having a diameter of at least 100 mm and a thickness of more than 80 μm, the germanium semiconductor wafer having a back side and a front side and is designed as a substrate, the method comprising:
forming at least two III-V layers on the front side, and a portion of the III-V layers forming a top surface of the semiconductor wafer;
patterning a first resist on the top surface in a first photolithography process, first resist-free regions being formed during the patterning for forming the through-opening;
applying the first resist in a patterned manner via a first printing process to form first resist-free regions;
removing, via a wet-chemical process, the layers arranged on the front side of the germanium semiconductor wafer, in the first resist-free regions to form an oval hole-shaped recess having a circumferential side surface and a base region from the front side of the germanium layer;
applying, after the removal of the first resist, a second resist to the top side and in the base region via a second photolithography process;
patterning the second resist in the base region of the recess to form second resist-free regions in the base region or the second resist being applied in a patterned manner to the top side and in the base region by a second printing process to form the second resist-free regions in the base region;
producing, in the second resist-free regions of the base region, a through-hole extending from the base region of the recess to the back side of the semiconductor wafer in the germanium layer via a laser process;
overetching, in a subsequent second wet-etching step, the through-hole and removing a portion of the germanium layer; and
completely removing the second resist to form the through-opening, a width of the recess in the through-opening being larger than a width of the through-hole.

2. The method for producing a through-opening according to claim 1, wherein the top surface having the first resist is protected against an etching attack outside the recesses to be produced when carrying out the first wet etching step.

3. The method for producing a through-opening according to claim 1, wherein the top surface and the side surfaces of the recess having the second resist are protected against an etching attack during the second wet etching step.

4. The method for producing a through-opening according to claim 1, wherein, in the base region, a circumferential first step is formed in the base region of the recess along the side surface when carrying out the laser process, the through-opening in the base surface having a maximum width in a range between at least 10 μm and no more than 400 μm or 20 μm to 200 μm, and a passage depth having a height corresponding to the thickness of the germanium semiconductor wafer.

5. The method for producing a through-opening according to claim 1, wherein the recess has a maximum width at the top surface in a range between 40 μm and 500 μm or in a range between 2 μm and 100 μm or in a range between 4 μm and 40 μm.

6. The method for producing a through-opening according to claim 1, wherein the recess has a minimum width at the top surface of more than 2 μm or more than 4 μm or more than 40 μm.

7. The method for producing a through-opening according to claim 1, wherein the III-V layers in the resist-free regions are completely removed when carrying out the first wet etching step, and wherein the base region is formed by the front side of the germanium semiconductor wafer.

8. The method for producing a through-opening according to claim 1, wherein the extension of the recess is determined in that the first resist is formed over the entire top surface of the semiconductor wafer in a first process step during the first photolithography process, wherein the first resist is exposed with the aid of a mask and developed in a second process step, or wherein the first resist is formed in a patterned manner on the top surface of the semiconductor wafer via the first printing process.

9. The method for producing a through-opening according to claim 1, wherein the side surfaces comprise III-V layers or are made up of III-V layers.

10. The method for producing a through-opening according to claim 1, wherein, in the first etching step, the acid has a selectivity greater than 10:1 for the purpose of etching the III-V layers much faster than the germanium layer.

11. The method for producing a through-opening according to claim 1, wherein the through-hole produced with the aid of the laser has a smaller maximum width and a smaller minimum width than the recess.

12. The method for producing a through-opening according to claim 1, wherein the step surface of the first step has a depth in a range between 0.05 μm and 20 μm or between 0.5 μm and 5 μm.

13. The method for producing a through-opening according to claim 1, wherein the opening is designed to be circular or as a circle in the recess and/or in the through-hole.

14. The method for producing a through-opening according to claim 1, wherein the III-V layers formed on the front side have a total thickness between 1 μm and 80 μm or a total thickness between 2 μm and 40 μm or a total thickness between 3 μm and 15 μm.

15. The method for producing a through-opening according to claim 1, wherein the through-opening has a second step in addition to the first step.
